(19) United States
(12) Patent Application Publication
(10) Pub. No.: US 2007/0033507 A1
(43) Pub. Date: Feb. 8, 2007

(54) Efficient error code correction

(76) Inventor: Xueping Jiang, San Jose, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/196,092

(22) Filed: Aug. 3, 2005

(51) Int. Cl. H03M 13/00

(52) U.S. Cl. 714/785

(57) ABSTRACT

In one embodiment of the invention, an error-correcting receiver includes an input buffer for storing received codewords, a first error correction syndrome circuit coupled to receive a first codeword and produce an output word, and a second error correction syndrome circuit coupled to receive a second codeword and produce an output word. An error-trapping-and-decoding circuit alternately receives the output words of the first and second error correction syndrome circuits. An error correction circuit coupled to the error-trapping-and-decoding circuit and the input buffer is adapted to provide corrected codewords.

### TECHNICAL FIELD

The present invention relates generally to error correction, and more particularly to an efficient implementation for error correction using cyclic codes.

### BACKGROUND

Coding systems using cyclic error codes such as cyclic redundancy check (CRC) techniques provide powerful error detection capabilities. Thus, CRC techniques are widely used in, for example, disk controllers, Internet protocols such as IP, and other networking protocols including Ethernet. In a CRC technique, a block of d data bits denoted as a frame is joined with an extra block of m bits called the frame check sequence (FCS), d and m being integers. Similar to a checksum, the FCS introduces redundancy into the transmitted (d+m) codeword that permits the receiver to detect errors. All of the bits are treated as binary coefficients of polynomials. A receiver will detect errors in the received (d+m) codeword by dividing (using polynomial arithmetic) the codeword with a generator polynomial. If the remainder from this division is zero, a CRC-enabled receiver will assume that the received codeword contains no errors.

Noise-induced errors may be classified into two types. A first type would be that produced by white noise, which results in randomly-distributed errors in a transmitted codeword. A second type would be that produced by burst noise, which results in correlated errors in a transmitted codeword. For example, in a code word having bit positions X0, X2, . . . , XN, . . . burst noise might result in errors in bit positions X0, X1, and X2. In contrast, white-noise-induced errors would be more randomly distributed throughout the transmitted codeword.

Various forms of cyclic error codes have been implemented to correct for burst errors. In particular, Fire code is one of the most efficient burst-error control codes. FIG. 1A illustrates a receiver 100 that decodes Fire-code-encoded words. As discussed above, cyclic codes such as Fire code require division of the received codewords with the generating polynomial such that the resulting error correction cannot be performed in real time. In other words, the received codewords arrive according to their frame rate, one codeword per frame. The division by the generating polynomial requires at least one frame. Because of this necessary delay, a received codeword 101 couples through a gate 102 (such as a transistor switch or transmission gate) into a FIFO data buffer 105. At the same time, the received codeword 101 couples through a gate 110 into an error correction syndrome correction circuit 120. As known in the art, the generating polynomial division takes place in the error correction syndrome circuit 120 and is typically implemented using a linear feedback shift register (LFSR) or equivalent circuitry. Error correction syndrome circuit 120 provides an output word 130 having the same width as received codeword 101. Should there be no errors, output word 130 would comprise all zeroes. If, however, there are errors, binary ones occur at the corresponding bit positions within output word 130.

An error-trapping and decoding circuit 125 receives the output from error correction syndrome circuit 120. As known in the art, error-trapping and decoding circuit 125 comprises logic that determines whether output word 130 contains errors that may be corrected. For example, Fire code enables the correction of burst errors distributed no more than seven bits apart. But should output word 130 comprise a sixteen-bit-wide word having errors in bit positions 1 and 10, such errors are more than seven bits apart. The logic within error-trapping and decoding circuit 125 would recognize such an error as being uncorrectable in a Fire code embodiment. In general, the types of errors that may be corrected depend upon the particular cyclic code implementation. If a correctable error (or no errors) are detected by error trapping and decoding circuit 125, error correction circuit 140 retrieves received codeword 101 from FIFO 105 and processes it responsive to output word 130 to provide corrected (if there are any errors) codeword 150. For example, error correction circuit 140 may XOR output word 130 and received codeword 101 to produce corrected (if necessary) codeword 150. The processing through error trapping and decoding circuit 125 and error correction circuit 140 requires another frame delay.

Thus, as seen in the timing diagram of FIG. 1B, a corrected codeword such as codeword 150 requires two frame periods for processing. For example, an nth received codeword is processed through error syndrome circuit 120 in a first frame period. In the 2^{nd} frame period, this nth codeword is processed through error correction circuit 140 to provide a corrected codeword 150. Similarly, in the third frame period, an (n+1)th received codeword is processed through error syndrome circuit 130. Finally, in the 4^{th} frame period, this (n+1)th received codeword is processed through error correction circuit 140 to provide another corrected codeword. Thus, for the four frame periods shown in FIG. 1B, only two corrected codewords 150 are provided. As such, receiver 100 outputs a corrected codeword at just half the frame rate of the received codewords.

To increase the output rate of corrected codewords, two receivers 100 may work in parallel such that each receiver processes every other received codeword. However, receiver 100 is often part of an integrated circuit, and duplicating the receiver leads produces an undesirable increase in the semiconductor die area and circuit power requirements. Accordingly, there is a need in the art for improved error-correcting receivers.

### SUMMARY

In accordance with an embodiment of the invention, an error-correcting receiver is provided that is adapted to process received codewords encoded with a cyclic code, the received codewords arriving according to a frame rate. The receiver includes: a first error correction syndrome circuit; a second error correction syndrome circuit, wherein the receiver is configured to alternatively select either the first error correction syndrome circuit or the second error correction syndrome circuit to process a received codeword in a given frame such that the remaining one of the first and second error correction syndrome circuits processes the received codeword in the frame subsequent to the given frame, and so on; the first and second error correction syndrome circuits thereby providing output words at the frame rate of the received codewords; and an error-trapping-and-decoding circuit adapted to determine whether the output words contain correctable errors.

In accordance with another embodiment of the invention, a method of error correcting received codewords is provided, the received codewords being encoded according to a cyclic code, the codewords being received according to a frame rate. The method includes the acts of: for a received codeword in a given frame, processing the received codeword in selected one of a first and second error correction syndrome circuits to provide a corresponding output word; for a received codeword in the frame subsequent to the given frame, processing the received codeword in a remaining one of the first and second error correction syndrome circuits to provide a corresponding output word; and so on such that the corresponding output words are provided at the frame rate of the received codewords; and for each of the output words, determining whether the output word contains correctable errors.

In accordance with another embodiment of the invention, an error-correcting receiver adapted to process received codewords encoded with a cyclic code, the received codewords arriving according to a frame rate is provided. The error-correcting receiver includes: an input buffer for storing the received codewords; a first error correction syndrome circuit coupled to receive a first codeword and produce an output word; a second error correction syndrome circuit coupled to receive a second codeword and produce an output word, an error-trapping-and-decoding circuit coupled to receive the output words of the first and second error correction syndrome circuits; and an error correction circuit coupled to the error-trapping-and-decoding circuit and the input buffer and adapted to provide corrected codewords.

### BRIEF DESCRIPTION OF THE DRAWINGS

FIG. 1A is a block diagram of a conventional error-correcting receiver.

FIG. 1B is a timing diagram for the error-correcting receiver of FIG. 1A.

FIG. 2A is a block diagram of an error-correcting receiver in accordance with an embodiment of the invention.

FIG. 2B is a timing diagram for the error-correcting receiver of FIG. 2A.

Use of the same reference symbols in different figures indicates similar or identical items.

### DETAILED DESCRIPTION

Reference will now be made in detail to one or more embodiments of the invention. While the invention will be described with respect to these embodiments, it should be understood that the invention is not limited to any particular embodiment. On the contrary, the invention includes alternatives, modifications, and equivalents as may come within the spirit and scope of the appended claims. Furthermore, in the following description, numerous specific details are set forth to provide a thorough understanding of the invention. The invention may be practiced without some or all of these specific details. In other instances, well-known structures and principles of operation have not been described in detail to avoid obscuring the invention.

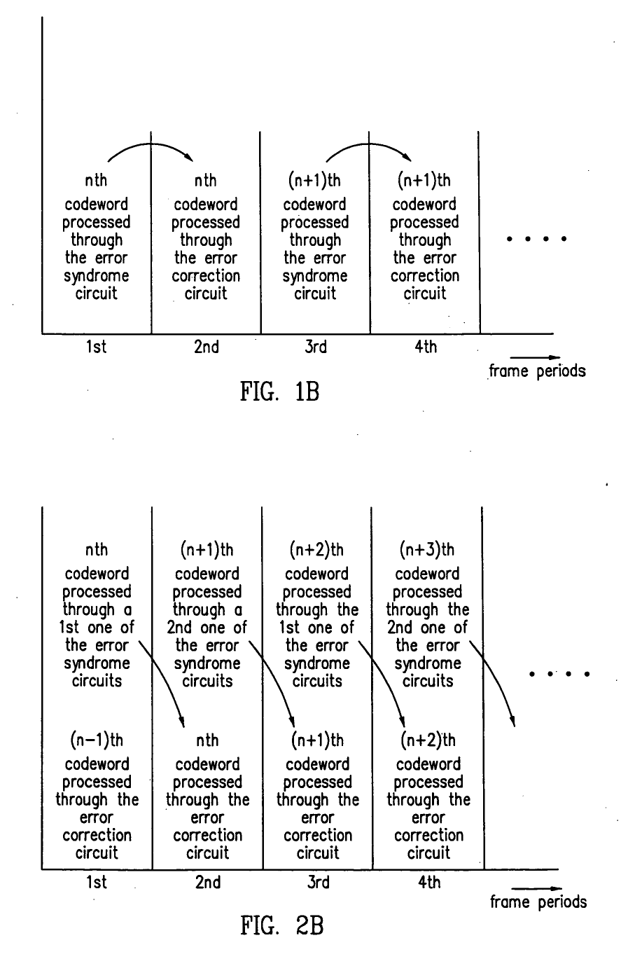

To avoid the duplication of hardware described above for conventional error correcting receivers, an improved error-correcting receiver architecture is disclosed. An exemplary embodiment of an error-correcting receiver 200 incorporating this improved architecture is illustrated in FIG. 2A. Receiver 200 may be incorporated into other devices such as a programmable logic device. An input buffer such as a FIFO 105 functions to buffer received codewords 101 as discussed previously. Received codewords are encoded with a cyclic code such as, for example, a Fire code that enables error correction. Receiver 200 is operable to alternately process each received codeword in a first error correction syndrome circuit 220 and a second error correction syndrome circuit 225.

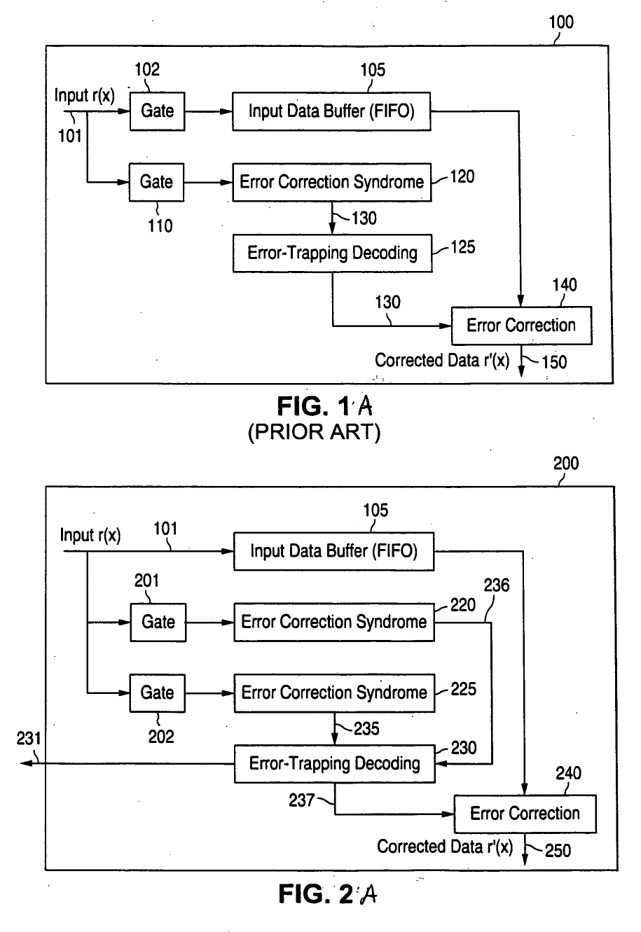

For example, suppose an nth received codeword is processed in first error correction syndrome circuit 220, n being a positive integer denoting a particular frame. An (n+1)th received codeword would then be processed in second error correction syndrome circuit 225, followed by the processing of an (n+2)th received codeword in first error correction syndrome circuit 220, and so on. For example, receiver 200 may include gates 201 and 202 coupled, respectively, between the input of receiver 200 and the inputs of circuits 220 and 225. Because corrected codewords may be processed at the received codeword frame rate, there is no need for a gating circuit at the input of input data buffer 105 in contrast to the prior art receiver 100 of FIG. 1A. Gates 201 and 202 are operated in reciprocating fashion to enable the alternating processing by syndrome circuits 220 and 225. In such an embodiment, gate 201 may be turned on and gate 202 may be turned off during the receipt of the nth codeword such that first error correction syndrome circuit processes this codeword as just described. Prior to the receipt of the (n+1)th codeword, gate 201 may be turned off and gate 202 turned on, and so on. Gates 201 and 202 may be implemented using transistor switches, transmission gates, or other suitable circuitry. A controller (not illustrated) may coordinate the alternative switching of gates 201 and 202. First and second error correction syndrome circuits 220 and 225 may comprise linear feedback shift registers or other suitable circuitry operable to divide the received codeword by the corresponding generating polynomial as known in the error correction arts.

For any given received codeword, either first error correction syndrome circuit 220 or second error correction syndrome circuit 225 will thus be the circuit selected for processing. This selected circuit may be denoted as the “current” selected circuit. The current selected error correction syndrome circuit will provide an output word to an error-trapping-and-decoding circuit 230. Error-trapping-and-decoding circuit 230 performs the necessary logic to determine whether correctable errors exist as discussed with respect to error-trapping-and-decoding circuit 125 of FIG. 1A. If first error correction syndrome circuit 220 has just processed a received codeword, this circuit would provide an output word 236 to error-trapping-and-decoding circuit 230. Alternatively, if second error correction syndrome circuit 225 has just processed a received codeword, then this circuit would provide an output word 235 to error-trapping-and-decoding circuit 230.

Regardless of which error correction syndrome circuit has processed the current received codeword, error-trapping-and-decoding circuit 230 may thus process a current output word (either output word 236 or output word 235 depending upon which error correction syndrome circuit has just performed the processing) at the frame rate of the received codewords. If the current output word being processed by error-trapping-and-decoding circuit 230 contains uncorrectable errors, circuit 230 may assert a flag 231 indicating that the corresponding received codeword must be re-transmitted. Alternatively, if error-trapping-and-decoding circuit 230 determines the current output word contains either no errors or correctable errors, circuit 230 transmits a processed word 237 to an error correction circuit 240. In addition, the corresponding received codeword is retrieved from input buffer 105 so that error correction circuit 240 may compare the received codeword to the current output word so as to provide a corrected codeword 250.

Advantageously, receiver 200 may provide corrected codewords 250 at the same frame rate as that for received codewords 101 without requiring duplication of entire receivers such as duplicates of receiver 100. This may be better illustrated with regard to the timing diagram of FIG. 2B for receiver 200. In a first frame period, an nth received codeword is processed through a first one of the error syndrome circuits 220 and 225. In the second frame period, this nth received codeword is processed through error correction circuit 240 while an (n+1)th received codeword is processed through the remaining one of error syndrome circuits 220 and 225. Similarly, in the third frame period, an (n+2)th received codeword is processed through the first one of the error syndrome circuits while error correction circuit processes the (n+1)th received codeword. In this fashion, a corrected codeword 250 may be provided at the frame rate of the received codewords. Thus, increased data throughput is achieved from error-correcting receiver 200 yet semiconductor die area demands and power consumption are minimized.

The above-described embodiments of the present invention are merely meant to be illustrative and not limiting. It will thus be obvious to those skilled in the art that various changes and modifications may be made without departing from this invention in its broader aspects. Accordingly, the appended claims encompass all such changes and modifications as fall within the true spirit and scope of this invention.

I claim:

1. An error-correcting receiver adapted to process received codewords encoded with a cyclic code, the received codewords arriving according to a frame rate, comprising:
a first error correction syndrome circuit;
a second error correction syndrome circuit, wherein the receiver is configured to alternatively select either the first error correction syndrome circuit or the second error correction syndrome circuit to process a received codeword in a given frame such that the remaining one of the first and second error correction syndrome circuits processes the received codeword in a frame subsequent to the given frame, and so on; the first and second error correction syndrome circuits thereby providing output words at the frame rate of the received codewords; and
an error-trapping-and-decoding circuit adapted to determine whether the output words contain correctable errors.

2. The error-correcting receiver of claim 1, wherein each output word corresponds to a unique one of the received codewords, the receiver further comprising:
an input buffer for storing the received codewords; and
an error correction circuit adapted to process output words from the error-trapping-and-decoding circuit with corresponding received codewords retrieved from the input buffer to provide corrected output words.

3. The receiver of claim 1, wherein the first and second error correction circuits comprise linear feedback shift registers.

4. The receiver of claim 1, further comprising:
an input port for receiving the received codewords;
a first gating circuit coupled to the input port and to an input of the first error correction syndrome circuit; and
a second gating circuit coupled to the input port and to an input of the second error correction syndrome circuit, wherein the receiver is adapted to alternatively select either the first or the second error correction syndrome circuit to process a received codeword by alternatively operating the first and second gating circuits in a reciprocating fashion such that if one of the first and second gating circuits is switched on, the remaining one of the first and second gating circuits is switched off.

5. The receiver of claim 4, wherein the first and second gating circuits comprise transmission gates.

6. The receiver of claim 4, wherein the first and second gating circuits comprises transistor switches.

7. The receiver of claim 2, wherein the error correction circuit comprises a plurality of XOR gates.

8. The receiver of claim 1, wherein the received codewords are encoded according to a Fire code, the first and second error correction syndrome circuits being adapted to process the received codewords through polynomial division according to a corresponding generating polynomial for the Fire code.

9. The error-correcting receiver of claim 2, wherein the input buffer includes a first-in-first-out (FIFO) buffer.

10. A method of error correcting received codewords, the received codewords being encoded according to a cyclic code, the codewords being received according to a frame rate, comprising:
for a received codeword in a given frame, processing the received codeword in selected one of a first and second error correction syndrome circuits to provide a corresponding output word
for a received codeword in the frame subsequent to the given frame, processing the received codeword in a remaining one of the first and second error correction syndrome circuits to provide a corresponding output word; and so on such that the corresponding output words are provided at the frame rate of the received codewords; and
for each of the output words, determining whether the output word contains correctable errors.

11. The method of claim 10, further comprising:
if the determining act determines that the output word contains correctable errors, processing the output word and the corresponding received codeword to provide a corrected output word.

12. The method of claim 10, wherein the received codewords are encoded according to a Fire code.

13. The method of claim 10, wherein the processing the received codewords comprises dividing the received codewords by a generating polynomial for the cyclic code.

14. The method of claim 10, further comprising:
if the determining act determines that the output word contains non-correctable errors, asserting a flag to signify that the corresponding received codeword should be re-transmitted.

15. The method of claim 11, wherein processing the output word and the corresponding received codeword to provide a corrected output word comprises performing an exclusive OR on the output word and the corresponding received codeword.

16. An error-correcting receiver adapted to process received codewords encoded with a cyclic code, the received codewords arriving according to a frame rate, comprising:
an input buffer for storing the received codewords;
a first error correction syndrome circuit coupled to receive a first codeword and produce an output word;
a second error correction syndrome circuit coupled to receive a second codeword and produce an output word,
an error-trapping-and-decoding circuit coupled to receive the output words of the first and second error correction syndrome circuits; and
an error correction circuit coupled to the error-trapping-and-decoding circuit and the input buffer and adapted to provide corrected codewords.

17. The error-correcting receiver of claim 16, including:
a first gating circuit coupled between an input of the error-correcting receiver and an input of the first error correction syndrome circuit; and
a second gating circuit coupled between an input of the error-correcting receiver and an input of the second error correction syndrome circuit.

18. The error-correcting receiver of claim 16, wherein the error-correcting receiver is incorporated into a programmable logic device.

19. The error-correcting receiver of claim 16, wherein the error-correcting receiver is adapted to alternately receive codewords from the first and second error correction syndrome circuits.

20. The error-correcting receiver of claim 16, wherein the input buffer includes a first-in-first-out (FIFO) buffer.
